(19) United States
(12) Patent Application Publication
(10) Pub. No.: US 2009/0277677 A1
(43) Pub. Date: Nov. 12, 2009

(54) Electronic Assemblies without Solder and Method for their Design, Prototyping, and Manufacture

(75) Inventors: Joseph C. Fjelstad, Maple Valley, WA (US); Nader Gamini, Cupertino, CA (US); David Tichane, Sunnyvale, CA (US)

Correspondence Address: The TPL Group, 20400 Stevens Creek Blvd., Fifth Floor, Cupertino, CA, 95014, US

(73) Assignee: OCCAM Portfolio LLC, Cupertino, CA (US)

(21) Appl. No.: 12/429,988

(22) Filed: Apr. 24, 2009

Related U.S. Application Data
(63) Continuation-in-part of application No. 12/119,287, filed on May 12, 2008.
Application No. 12/119,287 is a continuation-in-part of application No. 12/163,870, filed on Jun. 27, 2008.
Application No. 12/163,870 is a continuation-in-part of application No. 12/191,544, filed on Aug. 14, 2008.
Application No. 12/191,544 is a continuation-in-part of application No. 12/170,426, filed on Jul. 9, 2008.
Application No. 12/170,426 is a continuation-in-part of application No. 12/182,043, filed on Jul. 29, 2008.
Application No. 12/182,043 is a continuation-in-part of application No. 12/187,323, filed on Aug. 6, 2008.
Application No. 12/187,323 is a continuation-in-part of application No. 12/200,749, filed on Aug. 28, 2008.
Application No. 12/200,749 is a continuation-in-part of application No. 12/405,773, filed on Mar. 17, 2009.
Application No. 12/405,773 is a continuation-in-part of application No. 12/184,086, filed on Jul. 31, 2008.
Application No. 12/184,086 is a continuation-in-part of application No. 12/410,362, filed on Mar. 24, 2009.
(60) Provisional application No. 61/075,238, filed on Jun. 24, 2008.

(51) Int. Cl. H05K 1/18; H05K 13/00

(52) U.S. Cl. 174/260; 29/825

(57) ABSTRACT

A system for prototyping electrical circuits, as well as creating production circuits, without using solder. Stand-in electrical components 110a are placed on a carrier 100a and scanned 310. From the resulting data, a machine tool or laser ablation system 410 then creates a negative master 420a with aperture(s) 530 into which production components 810 are placed and secured. Component leads 820 or packages are encapsulated with electrically insulating material 910 with vias 1030a exposing the leads. Traces 1040 connect appropriate leads forming a circuit sub-assembly 1000 which can serve as a basis for a circuit assembly formed through a reverse-interconnection process.

### CROSS-REFERENCE TO RELATED APPLICATIONS

This application claims the benefit of U.S. Provisional Application No. 61/075,238 filed Jun. 24, 2008, hereby incorporated by reference in its entirety.

This application is a continuation-in-part application of pending U.S. patent application Ser. No. 12/119,287, ELECTRONIC ASSEMBLIES WITHOUT SOLDER AND METHODS FOR THEIR MANUFACTURE; U.S. patent application Ser. No. 12/163,870, ELECTRONIC ASSEMBLIES WITHOUT SOLDER AND METHODS FOR THEIR MANUFACTURE; U.S. patent application Ser. No. 12/191,544, ELECTRONIC ASSEMBLIES WITHOUT SOLDER AND METHODS FOR THEIR MANUFACTURE; U.S. patent application Ser. No. 12/170,426, ELECTRONIC ASSEMBLIES WITHOUT SOLDER AND METHODS FOR THEIR MANUFACTURE; U.S. patent application Ser. No. 12/182,043, ASSEMBLY OF ENCAPSULATED ELECTRONIC COMPONENTS TO A PRINTED CIRCUIT BOARD; U.S. patent application Ser. No. 12/187,323 SYSTEM FOR THE MANUFACTURE OF ELECTRONIC ASSEMBLIES WITHOUT SOLDER; U.S. patent application Ser. No. 12/200,749 ELECTRONIC ASSEMBLIES WITHOUT SOLDER AND METHODS FOR THEIR MANUFACTURE; U.S. patent application Ser. No. 12/405,773 MONOLITHIC MOLDED FLEXIBLE ELECTRONIC ASSEMBLIES WITHOUT SOLDER AND METHODS FOR THEIR MANUFACTURE; U.S. patent application Ser. No. 12/184,086 ELECTRONIC ASSEMBLIES WITHOUT SOLDER HAVING OVERLAPPING COMPONENTS; and U.S. patent application Ser. No. 12/410,362 ELECTRONIC ASSEMBLIES WITHOUT SOLDER AND METHOD FOR THEIR DESIGN, PROTOTYPING, AND MANUFACTURE, hereby incorporated by reference in their entirety.

### COPYRIGHT NOTICE/PERMISSION

A portion of the disclosure of this patent document contains material which is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD OF THE INVENTION

The present invention relates generally to the field of electronic assembly and more specifically, but not exclusively, to prototyping and assembly of electronic products without the use of solder.

### BACKGROUND

Prototyping, including rapid prototyping, technology has been developed to help expedite the production of numerous products to expose design issues before committing to hard tooling. These methods have largely been reserved for mechanical products; however, they have not been suitably applied to the creation of electronic assemblies and electronic products that do not require solder.

The assembly of electronic products, and more specifically the permanent assembly of electronic components to printed circuit boards, has involved the use of some form of relatively low-temperature solder alloy (e.g., tin/lead or Sn63/Pb37) since the earliest days of the electronics industry. The reasons are manifold but the most important one has been the ease of mass joining of thousand of electronics interconnections between printed circuit and the leads of many electronic components.

Lead is a highly toxic substance, exposure to which can produce a wide range of well-known adverse health effects. Of importance in this context, fumes produced from soldering operations are dangerous to workers. The process may generate a fume which is a combination of lead oxide (from lead based solder) and colophony (from the solder flux). Each of these constituents has been shown to be potentially hazardous. In addition, if the amount of lead in electronics were reduced, it would also reduce the pressure to mine and smelt it. Mining lead can contaminate local ground water supplies. Smelting can lead to factory, worker, and environmental contamination.

Reducing the lead stream would also reduce the amount of lead in discarded electronic devices, lowering the level of lead in landfills and in other less secure locations. Because of the difficulty and cost of recycling used electronics, as well as lax enforcement of legislation regarding waste exports, large amounts of used electronics are sent to countries such as China, India, and Kenya, which have lower environmental standards and poorer working conditions.

Thus, there are marketing and legislative pressures to reduce tin/lead solders. In particular, the Directive on the Restriction of the Use of Certain Hazardous Substances in Electrical and Electronic Equipment (commonly referred to as the Restriction of Hazardous Substances Directive or RoHS), was adopted in February 2003 by the European Union. The RoHS directive took effect on Jul. 1, 2006, and is required to be enforced and become law in each member state. This directive restricts the use of six hazardous materials, including lead, in the manufacture of various types of electronic and electrical equipment. It is closely linked with the Waste Electrical and Electronic Equipment Directive (WEEE) 2002/96/EC, which sets collection, recycling and recovery targets for electrical goods and is part of a legislative initiative to solve the problem of huge amounts of toxic electronic device waste.

RoHS does not eliminate the use of lead in all electronic devices. In certain devices requiring high reliability, such as medical devices, continued use of lead alloys is permitted. Thus, lead in electronics continues to be a concern. The electronics industry has been searching for a practical substitute for tin/lead solders. The most common substitutes in present use are SAC varieties, which are alloys containing tin (Sn), silver (Ag), and copper (Cu).

SAC solders also have significant environmental consequences. For example, mining tin is disastrous, both locally and globally. Large deposits of tin are found in the Amazon rain forest. In Brazil, this has led to the introduction of roads, clearing of forest, displacement of native people, soil degradation, and creation of dams, tailing ponds, and mounds, and smelting operations. Perhaps the most serious environmental impact of mining tin in Brazil is the silting up of rivers and creeks. This degradation modifies forever the profile of animal and plant life, destroys gene banks, alters the soil structure, introduces pests and diseases, and creates an irrecoverable ecological loss.

Worldwide ecological problems stemming from mismanagement of Brazil's environment are well known. These range from pressures on global warming from the destruction of rain forest to the long term damage to the pharmaceutical industry by the destruction of animal and plant life diversity. Mining in Brazil is simply one example of the tin industry's destructive effects. Large deposits and mining operations also exist in Indonesia, Malaysia, and China, developing countries where attitudes toward economic development overwhelm concerns for ecological protection.

SAC solders have additional problems. They require high temperatures, wasting energy, are brittle, and cause reliability problems. The melting temperature is such that components and circuit boards may be damaged. Correct quantities of individual alloy constituent compounds are still under investigation, and the long term stability is unknown. Moreover, SAC solder processes are prone to the formation of shorts (e.g., “tin whiskers”) and opens if surfaces are not properly prepared. Whether tin/lead solder or a SAC variety is used, dense metal adds both to the weight and height of circuit assemblies. Therefore, there is a need for a substitute for the soldering process and its attendant environmental and practical drawbacks.

While solder alloys have been most common, other joining materials have been proposed and/or used, such as so-called “polymer solders”, which are a form of conductive adhesive. Moreover, there have been efforts to make connections separable by providing sockets for components. There have also been electrical and electronic connectors developed to link power and signal carrying conductors described with various resilient contact structures, all of which require constant applied force or pressure.

At the same time, there has been a continual effort to put more electronics into ever smaller volumes. As a result, over the last few years there has been interest within the electronics industry in various methods for integrated circuit (IC) chip stacking within packages and the stacking of IC packages themselves, all with the intent of reducing assembly size in the Z or vertical axis. There has also been an ongoing effort to reduce the number of surface mounted components on a printed circuit board (PCB) by embedding certain components, mostly passive devices, inside the circuit board.

In the creation of IC packages, there has also been an effort to embed active devices by placing unpackaged IC devices directly inside a substrate and interconnecting them by drilling and plating directly to the chip contacts. While such solutions offer benefits in specific applications, the input/output (I/O) terminals of the chip can be very small and very challenging to make such connections accurately. Moreover, the device after manufacturing may not successfully pass burn in testing, making the entire effort valueless after completion.

Another area of concern is in management of heat, as densely packaged ICs may create a high energy density that can reduce the reliability of electronic products.

### SUMMARY OF THE INVENTION

The present invention provides a prototyping method which can be integrated with a reverse interconnection process (RIP) as detailed in this patent application counterparts. Stand-in components are placed onto a carrier. The components are scanned with a suitable system, such as a computerized laser, to measure and record the measurements of the structure in X, Y and Z dimensions.

Data from the measurement step is used to create a three-dimensional structure in either positive or negative format, depending on what methods will be used in subsequent processing. Material can be ablated employing a laser, for example, or etched or milled from a blank with a machine tool, to create either a positive or negative master. Optionally, having created a master from one surface of a blank, the process can be repeated on another surface of the blank. After initial creation, negative masters can be used to mold positive masters and vice versa.

For prototyping, the negative masters can support production components, preferably pre-tested and burned in, including electrical, electronic, electro-optical, electromechanical and user interface devices with external I/O contacts, for subsequent processing and interconnection with conductive circuits. Also, negative masters can be suitable for small volume production. For a larger quantity of circuit assemblies, negative masters can be created from positive masters. That is, the masters produced can form the basis for creating tooling for mass production.

Once a negative master is positioned, components can be placed into apertures formed in the master. Then additional RIP steps can be employed to create circuit assemblies as detailed in the applications cited above. RIP comprises encapsulating a set of electronic components in electrically insulating material with leads exposed, covering the leads with a layer of electronically insulating covering material, creating vias extending from a surface of the layer of the covering material to the leads (thus exposing the leads), filling the vias with electrically conductive material and forming traces among the vias. Repeated steps of applying more electronically insulating covering material over the traces, accessing traces and/or leads by additional vias, filling the additional vias with electronically conductive material, and forming new traces will result in a total number of desired circuit connections.

Electronic assemblies without solder can be created as detailed in U.S. patent application Ser. No. 12/119,287 and U.S. patent application Ser. No. 12/187,323, beginning with the process detailed above for creating negative masters. Components are placed or glued with leads up into negative master apertures. This sub-assembly is encapsulated with a solder mask, dielectric, or electrically insulating covering material with holes, known as vias, formed or drilled through the covering material to the components' leads, conductors, and terminals. As an alternative to vias, encapsulating material can be removed (for example by ablating, etching, or milling) to a depth exposing the leads. Vias, if present, can be filled with electrically conductive material and/or traces formed on a resulting sub-assembly and the encapsulation and the process of forming or drilling vias repeated as desired to build up additional circuit layers. Optionally, the negative master can be removed, thus leaving the encapsulating material as support.

Alternatively, components can be placed or glued into the apertures with leads down. Then the components can be encapsulated as indicated above. Vias can then be created, if not pre-formed, through the negative master, instead of through the encapsulating material, to the leads and/or to circuit layers built within the negative master. As above, vias are not required; material can be removed from the negative master to expose leads. Even encapsulating material is optional; components can be placed or glued, for example, into apertures.

The master can also be created as a frame with circuitry subsequently built up as detailed in U.S. patent application Ser. No. 12/200,749. A negative master created as a frame containing aperture(s) is positioned on and joined to a temporary or permanent substrate. A pick and place machine, for example, places electrical component(s) into respective aperture(s) with the leads of the component(s) positioned on and attached to the substrate. Then an encapsulant electrically insulating, but preferably thermally conductive, envelops the component(s). At this point, a temporary substrate can be removed, exposing component leads. Or, if components are mounted on a permanent substrate, vias extend from the surface to the leads. With leads exposed, the completed sub-assembly can be incorporated into various forms.

In another example of the process of forming assemblies from the sub-assembly described in this application, component terminals are connected to a first side of a firmament with an anisotropic conductor. A pattern is applied to a second side of the firmament. And portions of the firmament are removed based on the pattern, such that remaining portions of the firmament form an electrical circuit interconnecting the component terminals of the electronic components. See U.S. patent application Ser. No. 12/170,426.

The negative master can be temporary so that following the creation of the sub-assembly or assembly, it can be removed. Also, electrically encapsulating material or covering material can be flexible so that when the negative master is removed or selectively thinned, the assembly can be bent into a desired shape. See U.S. patent application Ser. No. 12/163,870 and U.S. Patent Application No. 61/075,238.

Components can be placed in aperature(s) in a first and a second master, each encapsulated and further RIP circuit layers built up on each master. These two masters can be mated front to front, front to back, or back to back. See U.S. patent application Ser. No. 12/191,544.

Within negative master aperture(s), components can be stacked upon each other and electrically interconnected and integrated. See U.S. patent application Ser. No. 12/184,086.

In combination with the above methods and assemblies, components can be placed further in communication with one or more printed circuit board(s). After creating the negative master, placing component(s) therein, optionally encapsulating the components(s), exposing component lead(s), optionally removing the negative master, and building up RIP layers, component leads can be registered with respective printed circuit board leads. Then an electrically conductive joining material with intermediate conductors can be placed in communication with both component leads and the printed circuit board. Thus, encapsulated components, joining material, and the printed circuit board are in electrical communication by means of conductors. The electrically conductive joining material can be surrounded by an adhesive joining material to provide additional support. See U.S. patent application Ser. No. 12/182,043. The order of the above steps can be changed and still be within the scope of this invention. For example, after the printed circuit board is joined with the component lead(s), the negative master can be removed.

Monolithic molded flexible electronic methods can be employed and assemblies formed, starting with the process detailed in this application, as described in U.S. patent application Ser. No. 12/405,773. That is, in summary, masters formed as described above can form a first mold portion and a second mold potion that mate together to form an interior chamber, wherein the combination mold has an injection port that connects into an injection channel that connects into the chamber. A plurality of electronic parts that have electronic contacts are populated onto the second mold portion, such that the electronic parts will be substantially contained in the chamber. The first and the second mold potions are then mated together and an insulating molding material in a liquid state is injected into the injection port and through the injection channel to fill the chamber. The molding material is hardened from the liquid state to a solid state, thereby embedding the plurality of electronic parts in the molding material as a monolithic sub-assembly. The monolithic sub-assembly is removed from the mold and one or more solderless conductive circuits are applied to the electronic contacts of the electronic parts, thereby providing the monolithic molded electronic assembly. The result is an article of manufacture made by this method.

Another result of the monolithic molded flexible electronic process is a circuit assembly including a plurality of electronic parts that have electronic contacts. The electronic parts are over-molded with a flexible hardening insulating molding material to a first thickness, to have areas between sub-pluralities of the electronic parts having a different second thickness, thereby forming a monolithic sub-assembly. And the monolithic sub-assembly has at least one solderless layer of conductive circuits interconnecting the electronic contacts of the electronic parts.

An advantage of the monolithic molded flexible electronic method is the ability to make an assembly that can be bent into desired shapes.

As will be apparent to one skilled in the art, the above methods and assemblies can be combined in various combinations and permutations.

These and other objects and advantages of the present invention will become clear to those skilled in the art in view of the description of the best presently known mode of carrying out the invention and the industrial applicability of the preferred embodiment as described herein and as illustrated in the figures of the drawings.

### BRIEF DESCRIPTION OF THE SEVERAL VIEWS OF THE DRAWINGS

The purposes and advantages of the present invention will be apparent from the following detailed description in conjunction with the appended figures of drawings, in which:

FIG. 1 depicts placement of stand-in components on a carrier.

FIG. 2 is perspective view of stand-in components in place on a carrier.

FIG. 3 depicts a scanning system.

FIG. 4a depicts a master creation system.

FIG. 4b depicts a two-sided negative master.

FIG. 5 is a perspective view of a negative master.

FIG. 6 depicts a positive master.

FIG. 7 is a perspective view of a positive master.

FIG. 8 is a perspective view of a negative master with production electrical components in place.

FIG. 9 is a perspective view of a negative master with production electrical components in place with an electrically insulating cover.

FIG. 10 depicts a RIP sub-assembly.

FIG. 11 depicts a two-sided negative master with production electrical components in place with two of the components stacked upon each other.

FIG. 12 depicts a negative master formed with a two-dimensional prototyping system.

FIG. 13 depicts a negative master formed with a two-dimensional prototyping system with components being placed lead side down.

FIG. 14 depicts a negative master with encapsulating material covering production component packaging.

In the various figures of the drawings, like references are used to denote like or similar elements or steps.

### DETAILED DESCRIPTION

In the following description and in the accompanying drawings, specific terminology and drawing symbols are set forth to provide a thorough understanding of the present invention. In some instances, the terminology and symbols can imply specific details that are not required to practice the invention.

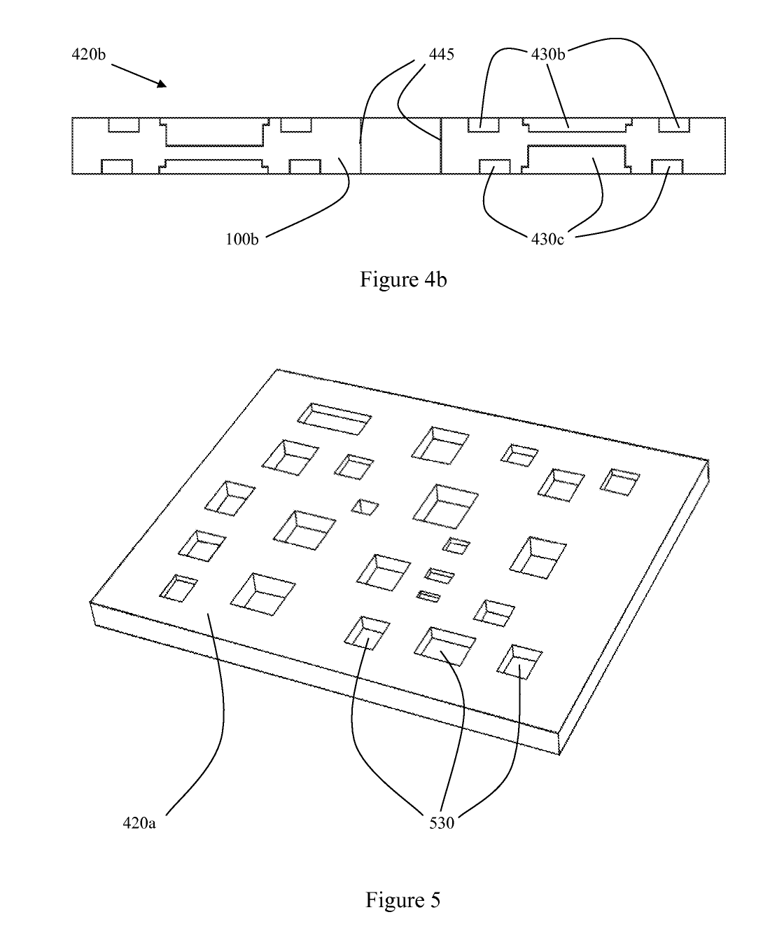

FIG. 1 shows placing of example stand-in components 110a onto a carrier 100a in a specified layout. Carrier 100a is shown as a planar base for illustrative purposes in this application, but it will be apparent to one skilled in the art that non-planar bases can be substituted. While components 110a are shown lead side down, they also could be positioned lead side up, or in any combination of up and down. If a two-sided assembly is desired, other components can be placed on a second carrier (see FIG. 4b and accompanying description). One or more spacer components (not shown in this view) can be incorporated to allow for side to side connections using via grid components as described in related U.S. patent application Ser. No. 12/191,544.

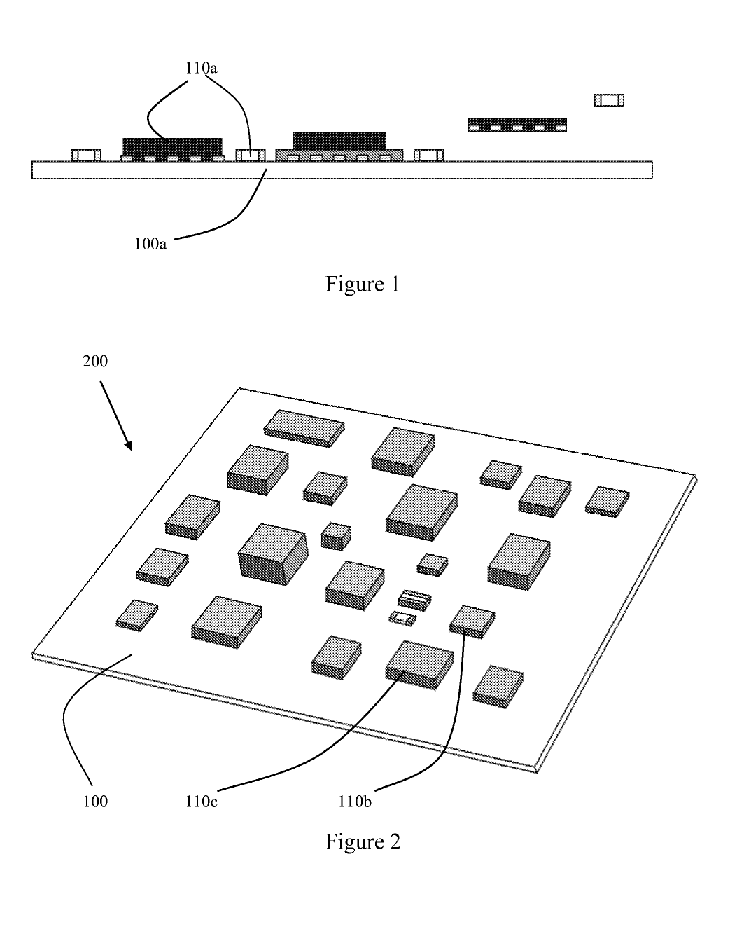

A perspective view of a stand-in component assembly 200 is illustrated in FIG. 2. Stand-in components 110c and 110b have been placed in registered positions on carrier 100. Desirably, taller components, such as stand-in component 110c, are positioned opposite shorter components, such as stand-in component 110b, to create a lower profile final assembly. As stated above, for a two-sided assembly, a second stand-in component assembly can be prepared on a second carrier using complementary components and with one or more optional spacer components registered with assembly 200.

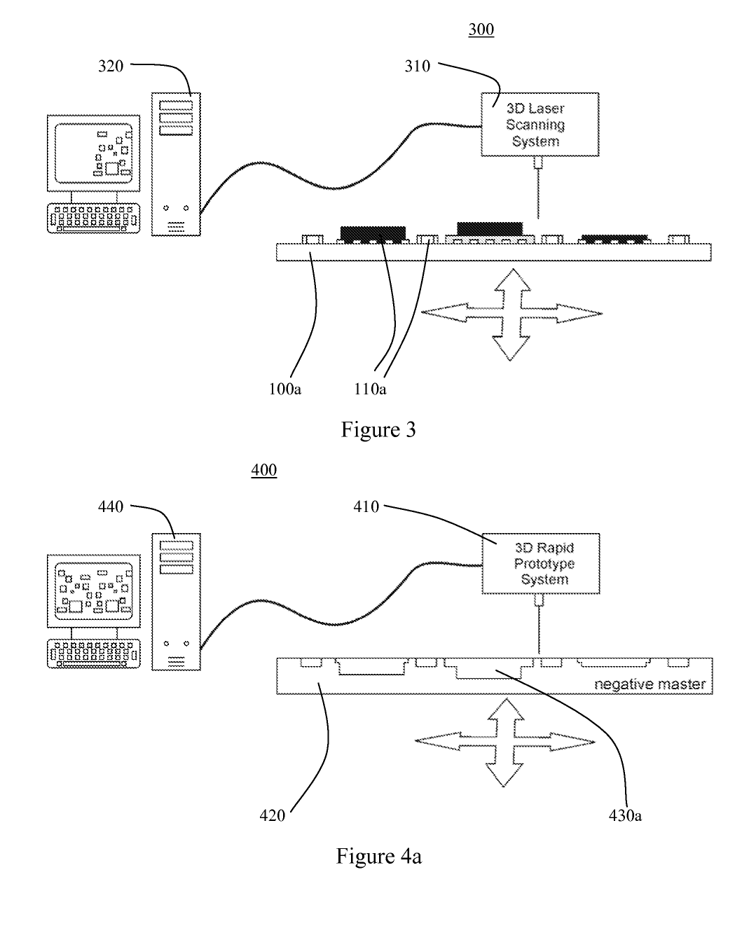

FIG. 3 shows a scanner system 300, incorporating, for example, computer driven laser scanning system 310 that can scan stand-in components, such as components 110a, placed in registered positions on carrier 100a. Computer 320 records data relating to a three-dimensional (X, Y, and Z axis) measurement of components 110a and their relative placement on carrier 100a.

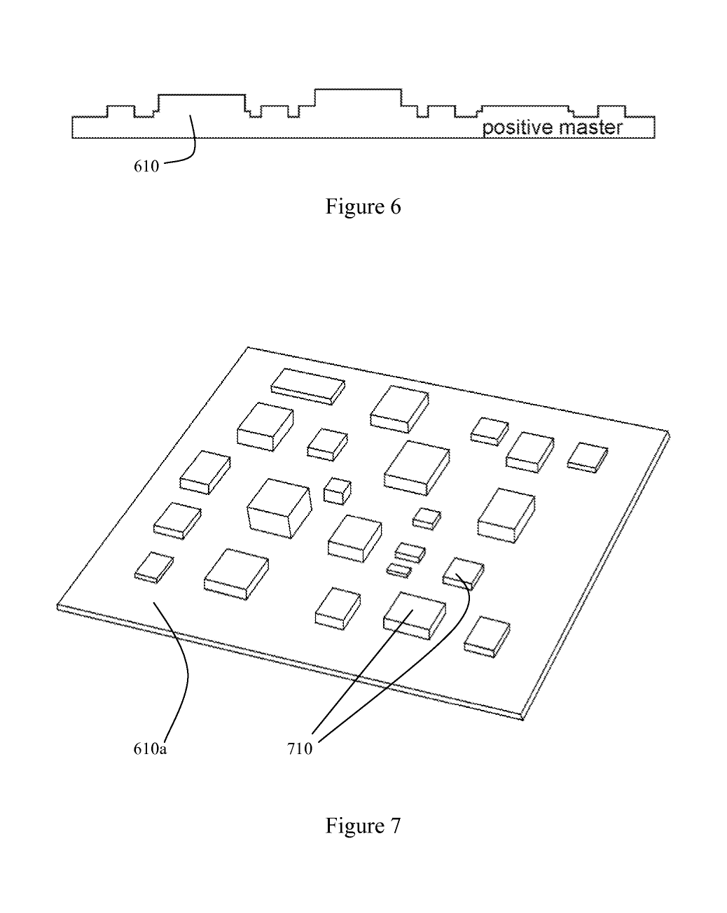

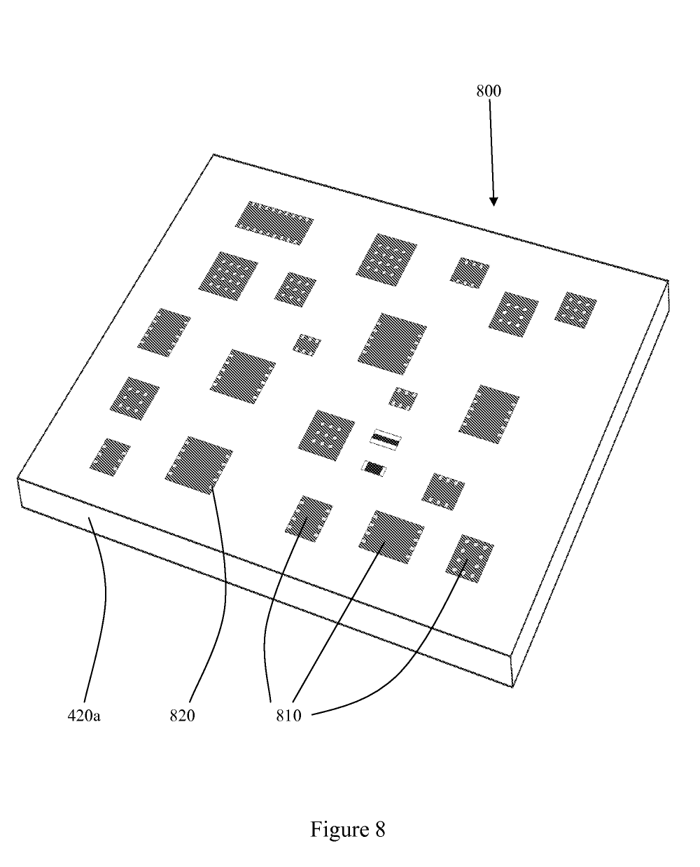

As shown in FIG. 4a, a system 400 can create a master. A computer 440 uses data generated from the measurement step illustrated in FIG. 3 to drive three-dimensional prototyping system 410 to create a negative master 420. For the purposes of this application, including claims, the term “master” shall encompass a master directly created by prototyping system 410, as well as production masters, bases, or carriers formed or molded from a master. If desired, system 410 can produce a positive master 610 (FIG. 6 and FIG. 7). Or, employing molding techniques, negative master 420 can create positive masters. Likewise, positive master 610, produced by system 410, can create negative masters. For prototyping, production component(s) can be placed and incorporated into negative master 420 aperture(s), such as aperture 430a, for subsequent processing and interconnection with conductive circuits.

System 410 can remove material from negative master 420 in a manner known in the art including milling, etching, or laser ablation.

As illustrated in FIG. 4b, a two-sided (or more) negative master 420b can be created. A preferred method of creating negative master 420b would be to have the scanner system 300, illustrated in FIG. 3, gather data from first and second stand-in component assemblies, each analogous to stand-in component assembly 200, illustrated in FIG. 2. The system 400, illustrated in FIG. 4a, can create apertures, such as apertures 430b, based on the first stand-in component assembly, on a first side of a carrier 100b. Then system 400 can create apertures, such as apertures 430c, based on the second stand-in component assembly, on a second side of carrier 100b. The result is apertures 430b and 430c on two sides of carrier 100b, forming negative master 420b. The process can be repeated for additional sides of carrier 100b. Alternatively, system 410 can produce positive masters which in turn can produce apertures on sides of carrier 100b. In yet another alternative, two or more negative masters, analogous to master 420a, can be used to produce positive masters which in turn can produce apertures on sides of carrier 100b. Or two or more negative masters can be mated.

In master 420b, one or more pathways, such as pathways 445 (for electrical conductors, electrical wiring, fluid, or coolant, for example), can be formed to extend from one side to another side of carrier 100b. Pathways can extend horizontally through carrier 100b, as well as vertically.

Having described a preferred technique, modifications, for example, molding a master into a side of carrier 100b, will be apparent to one skilled in the art. Given the underlying inventive technique and resulting product, such equivalent modifications are within the scope and spirit of the invention.

FIG. 5 is a perspective view of negative master 420a after completion of system 410 processing (shown in FIG. 4a). Apertures 530 will accept production components for a prototype or production assembly.

The three-dimensional prototyping system 410 of FIG. 4a can use data generated from the measurement step illustrated in FIG. 3 to create a positive master 610 shown in FIG. 6. The output can either be a tool or be used to create a tool for molding or forming negative masters.

FIG. 7 is a perspective view of positive master 610a (see cross-section of positive master 610 in FIG. 6). Raised surfaces 710 recreate the shapes of the scanned stand-in components, such as stand-in components 110c and 110b (FIG. 2). The surfaces 710 can be prepared with tapered edges to create a bevel, to facilitate component placement in aperture(s). Tapered edges can also facilitate mold release.

The production of prototyping assembly is accomplished by a series of steps. A perspective view of sub-assembly 800, shown in FIG. 8, illustrates the step of filling apertures of the negative master 420a with production components 810. These can be attached with adhesive if desired; the adhesive is preferably thermally conductive. Leads, such as lead 820, can be flush with a surface of negative master 420a. The negative master 420a can be pre-plated with metal or can be made directly from metal, depending on the process. Advantages of optional pre-plating or metal construction include enhanced heat dissipation, grounding, and protection from electrical surges, radio frequency noise and surges, and electromagnetic disturbances. Thin insulation can be used where needed.

In the example of sub-assembly 800, face up leads are shown flush with a surface of negative master 420a. In an alternative embodiment, leads such as lead 820 do not have to be flush with the surface.

While sub-assembly 800 shows production components 810 with their leads (such as lead 820), facing up, some or all components 810 can be inserted with their leads facing down. If leads are inserted facing down, access to them can be by way of laser ablation, milling, drilling, or etching through the negative master 420a.

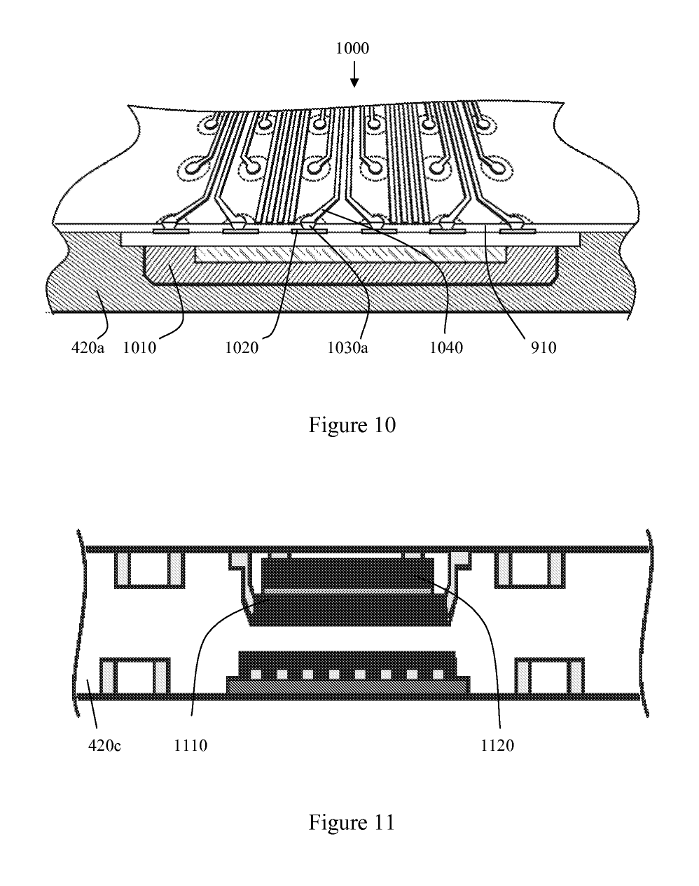

At this point, sub-assembly 800 can be further developed by the reverse-interconnection process (RIP) and variations disclosed in the related patent applications cited above. For example, FIGS. 10, 11, 12, 13, 14, 15, 16, and 17 and accompanying detailed description in U.S. patent application Ser. No. 12/119,287 illustrate and describe a method and resulting apparatus of building up RIP circuitry. The techniques in that disclosure can be employed using sub-assembly 800 as an initial starting point.

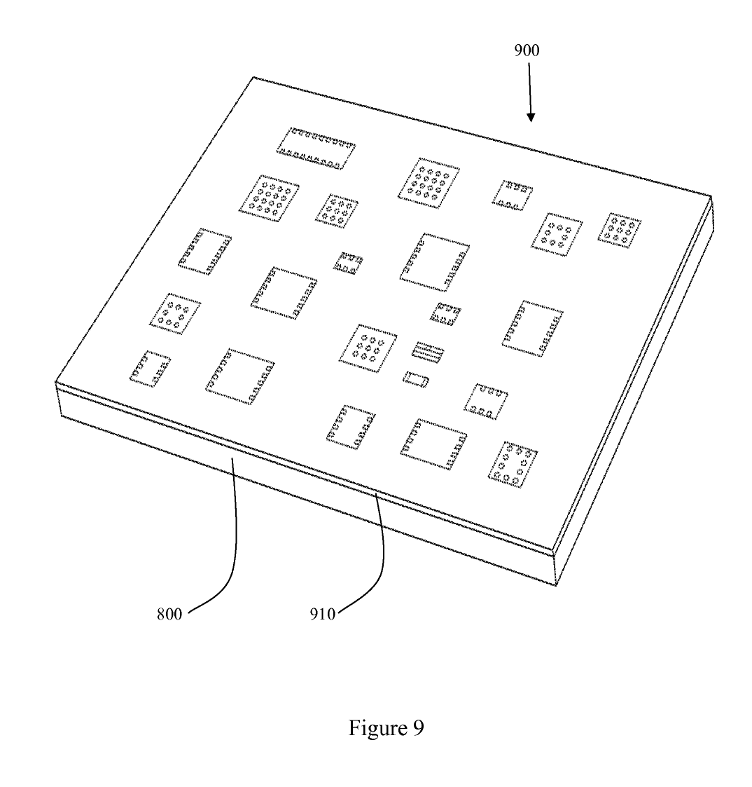

In FIG. 9, a subsequent process step is shown where a layer of electrically insulating material 910 is placed over the sub-assembly 800 as either a wet or dry film, resulting in sub-assembly 900. It can be performed in concert with a vacuum process to assure the exclusion of air. The coating can be photo-imageable, if desired, to access circuit features with photolithographic methods. Or access to circuit features such as lead 820 can be by vias. Sub-assembly 900 can then be incorporated into a RIP system.

FIG. 10 shows a one layer circuit sub-assembly 1000. Production component 1010 has been inserted into negative master 420a. Vias, such as via 1030a, extend from a top surface of insulating material 910 to component 1010 leads, such as lead 1020. Vias have been filled with electrically conductive material and interconnected by traces, such as trace 1040. The result is that component 1010 leads are interconnected with leads of other components. If further processing is desired, the circuit sub-assembly 1000, by means of additional RIP steps, can be integrated with additional material to form a completed assembly.

U.S. patent application Ser. No. 12/184,086, referenced above, describes electronic components stacked upon each other and electrically interconnected and integrated through RIP. That is, to improve the density of electrical components in a circuit assembly, components can be overlapped. FIG. 11 shows component 1110 and component 1120 stacked in that manner and inserted into an aperture of a negative master 420c. Circuitry can then be built upon components 1110 and 1120 through RIP and the resulting assembly manipulated and combined with other RIP assemblies, as detailed in related applications.

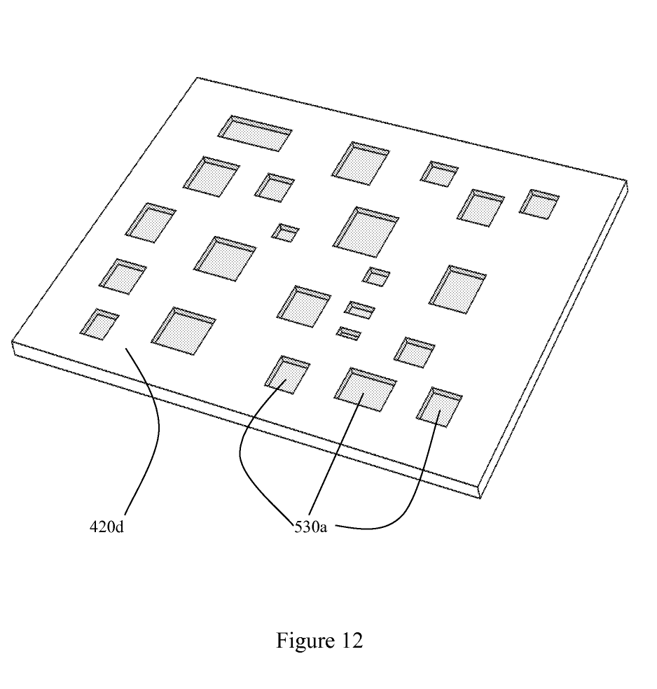

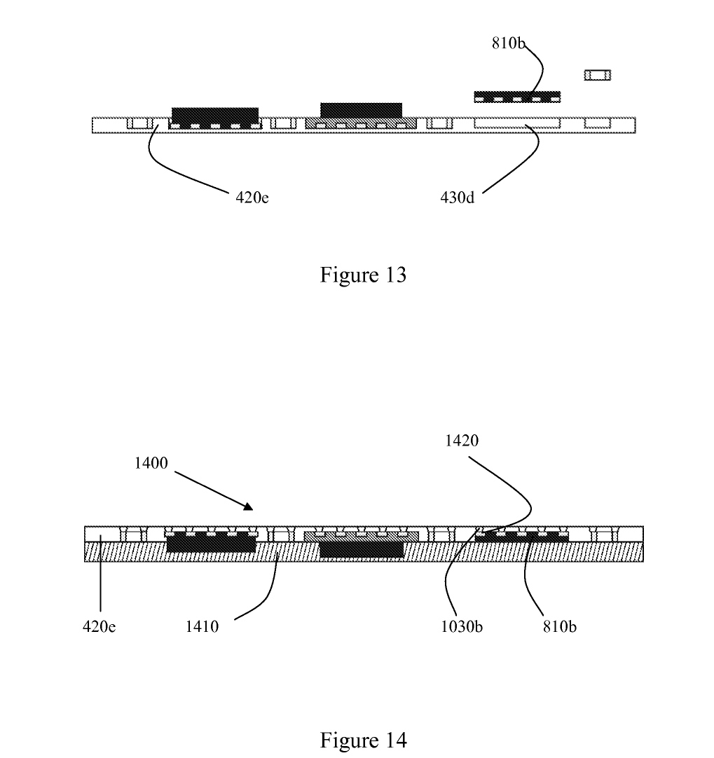

Data gathered by system 300, shown in FIG. 3, can create an X-Y only master (either positive or negative) which can then create, or be used as, a master wherein all apertures have a common depth and a thin and uniform base. The system 300 can create a two-dimensional negative master 420d, such as shown in FIG. 12. In this configuration, apertures such as apertures 530a have a common depth. The common depth is useful for accessing components from the bottom side of negative master 420d. That is, as shown in FIG. 13, production components, such as component 810b, can be inserted leads down into apertures, for example, aperture 430d. Component 810b can be bonded into place and leads accessed from the bottom of production master 420e by vias created by laser or other suitable formation processes (e.g., drilling or molding).

Next, referring to FIG. 14, shown is negative master 420e flipped from top to bottom so that the leads are now facing up. Optional encapsulation material 1410 is applied to cover production components, such as component 810b, on the current bottom of the master 420e. Access to component leads is by vias such as via 1030b, that extend through the material composing the master 420e from the top to component leads, such as lead 1420. Further RIP steps can build upon this sub-assembly 1400.

While the process and apparatuses have largely been described for prototyping, it can be suitable for small volume production. In addition, the masters produced can be used for creating tooling for mass production.

In regard to RIP assembly, negative master 420a can substitute for electrically insulating material 908 in FIG. 9 of U.S. patent application Ser. No. 12/119,287 ('287 application). Then various combinations, as illustrated in FIGS. 5, 6, 7, and 19, employing the steps (and sub-assemblies) illustrated in FIGS. 8, 9, 10, 11, 12, 13, 14, 15, 16, 17, and 18, of the '287 application can be built, employing RIP, from negative master 420a of the present application (see also the accompanying detailed description of invention and drawings in '287 application).

In another example, negative master 420a can substitute for electrically insulating material 908 of FIG. 9 and electrically insulating material 2004 in FIG. 20 of U.S. patent application Ser. No. 12/163,870 ('870 application). Then various combinations illustrated in FIGS. 5, 6, 7, 17, 19, 21, employing the steps (and sub-assemblies) illustrated in FIGS. 8, 9, 10, 11, 12, 13, 14, 15, 16, 17, 18, 19, 29, 30, 31, 32, 33, and 34, of the '870 application can be built upon the sub-assembly 800 of the present application (see also accompanying detailed description of invention and drawings in '870 application).

In another example, negative master 420a can substitute for insulating material 908 of FIG. 9 of U.S. patent application Ser. No. 12/191,544 ('544 application). Then combinations illustrated in FIGS. 19, 22, 23, 25, 27, 29, 30, 32, and 33, employing the steps (and subassemblies) illustrated in FIGS. 24, 26, and 28, of the '544 application can be built upon the sub-assembly 800 of the present application (see also accompanying detailed description of invention and drawings in '544 application).

In yet another example, negative master 420a can substitute for top cover material 416 in FIG. 4 of U.S. patent application Ser. No. 12/170,426 ('426 application). Then the combination illustrated in FIG. 11, employing the steps (and sub-assemblies) illustrated in FIGS. 12, 7, 8, 9, 10, 11, of the '426 application can be built upon the sub-assembly 800 of the present application (see also accompanying detailed description of invention and drawings in '426 application).

In a further example, negative master 420a can substitute for electrically insulating material 404 in FIG. 4 of U.S. patent application Ser. No. 12/182,043 ('043 application). Then the combination illustrated in FIG. 9, employing the steps (and sub-assemblies) illustrated in FIG. 8, of the '043 application can be built upon the sub-assembly 800 of the present application (see also accompanying detailed description of invention and drawings in '043 application).

In a further example, negative master 420a can substitute for insulating material 104 in FIG. 1 of U.S. patent application Ser. No. 12/184,086 ('086 application). Then the combinations illustrated in FIGS. 1, 2, 3, 4, 5, 6, 7, 8, 9, and 10 in the '086 application can be built upon the sub-assembly 800 of the present application (see also accompanying detailed description of invention and drawings in '086 application).

In a further example, negative master 420a can substitute for electrically insulating material 404 in FIG. 4 of U.S. patent application Ser. No. 12/187,323 ('323 application). Then the combinations illustrated in FIGS. 5, 6, and 7 employing the steps (and apparatus) illustrated in FIG. 8 of the '323 application can be built upon the sub-assembly 800 of the present application (see also accompanying detailed description of invention and drawings in '323 application).

In a further example, negative master 420a can be thinned in places such as illustrated in FIG. 1E of U.S. patent application Ser. No. 12/405,773 ('773 application). Then a resulting structure illustrated in FIG. 1G employing the steps (and sub-assemblies) illustrated in FIGS. 1E, 1F, and 1G of the '773 application can be built upon the sub-assembly 800 of the present application (see also accompanying detailed description of invention and drawings in '773 application).

While the particular system, apparatus, and method for ELECTRONIC ASSEMBLIES WITHOUT SOLDER AND METHOD FOR THEIR DESIGN, PROTOTYPING, AND MANUFACTURE as herein shown and described in detail, is fully capable of attaining the above-described objects of the invention, it is to be understood that it is the presently preferred embodiment of the present invention, and is thus representative of the subject matter which is broadly contemplated by the present invention, that the scope of the present invention fully encompasses other embodiments which can become obvious to those skilled in the art, and that the scope of the present invention is accordingly to be limited by nothing other than the appended claims, in which reference to an element in the singular means “at least one”. All structural and functional equivalents to the elements of the above-described preferred embodiment that are known or later come to be known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public, regardless of whether the element, component, or method step is explicitly recited in the claims.

We claim:

1. A method for creating electrical circuits comprising:
forming a negative master (420a) having one or more apertures (530),
inserting one or more electrical components (810) respectively into the one or more apertures (530), and
employing a reverse-interconnection process to build a circuit assembly.

2. A method for creating electrical circuits comprising:
forming a negative master (420e) having one or more apertures (430d) wherein the negative master (420e) comprises electrically insulating material,
inserting one or more electrical components (810b), having one or more leads (1420), respectively into the one or more apertures (430d) wherein one or more of the one or more leads (1420) are in communication with a surface of the one or more apertures (430d), and employing a reverse-interconnection process to build a circuit assembly.

3. The method of claim 2 wherein the reverse-interconnection process comprises:
accessing the one or more leads (1420) with one or more vias (1030b) extending from a surface of the master (420e) to the one or more leads (1420).

4. The method of claim 1 wherein inserting the one or more electrical components (810) comprises stacking one or more of the one or more electrical components (810).

5. The method of claim 2 wherein inserting the one or more electrical components (810b) comprises stacking one or more of the one or more electrical components (810b).

6. A product formed by the method of claim 1.

7. A product formed by the method of claim 2.

8. A product formed by the method of claim 3.

9. A product formed by the method of claim 4.

10. A product formed by the method of claim 5.

11. A method for creating electrical circuits comprising:
placing a first set of stand-in components (110a) on a first carrier (100a), scanning relative positions of the components (110a) and obtaining data on the positions, and
creating one or more masters from the data.

12. The method of claim 11 wherein creating one or more masters from the data comprises creating one or more negative masters (420a), wherein each of the one or more negative masters has one or more apertures (530).

13. The method of claim 11 wherein creating one or more masters from the data comprises creating one or more positive masters (610a), wherein each of the one or more positive masters (610a) has one or more raised surfaces (710).

14. The method of claim 13 further comprising the step of forming one or more negative masters (420a) from the one or more positive masters (610a) wherein each of the one or more negative masters (420a) has one or more apertures (530).

15. The method of claim 11 wherein creating one or more masters from the data comprises creating one or more two-sided negative masters (420b) wherein each of the one or more two-sided negative masters has one or more apertures (430b, 430c).

16. The method of claim 11 wherein creating one or more masters from the data comprises creating one or more masters each with a plurality of sides wherein at least three of the sides have one or more apertures.

17. The method of claim 12 further comprising inserting one or more production components (810) respectively into the one or more apertures (530).

18. The method of claim 14 further comprising inserting one or more production components (810) respectively into the one or more apertures (530).

19. The method of claim 15 further comprising inserting one or more production components respectively into the one or more apertures (430b, 430c).

20. The method of claim 16 further comprising inserting one or more production components respectively into the one or more apertures.

21. The method of claims 17, 18, 19, or 20 comprising placing one or more leads of the one or more production components in contact with a surface of the one or more apertures and accessing the one or more leads with one or more vias extending from a surface of the master to the one or more leads.

22. The method of claim 17 wherein at least two of the production components (810b) are stacked.

23. The method of claim 18 wherein at least two of the production components (810b) are stacked.

24. The method of claim 19 wherein at least two of the production components (810b) are stacked.

25. The method of claim 20 wherein at least two of the production components (810b) are stacked.

26. The method of claim 21 wherein at least two of the production components (810b) are stacked.

27. The method of claims 17, 18, 19, 20, 22, 23, 24, 25, or 26 further comprising employing a reverse-interconnection process to build a circuit assembly.

28. The method of claim 21 further comprising employing a reverse-interconnection process to build a circuit assembly (1000).

29. A product formed by the method of claim 11.

30. A reverse-interconnect process electrical circuit subassembly comprising:
a negative master (420a) with one or more apertures (530),
one or more electrical components (810), having one or more leads (820), respectively inserted into the one or more apertures (530), and
electrically insulating material (910) covering the one or more leads (820).

31. The subassembly of claim 30 further comprising:
one or more vias extending through the electrically insulating material (910) and exposing the one or more leads.

32. A reverse-interconnect process electrical circuit subassembly comprising:
a negative master (420e) with one or more apertures (430d),
one or more electrical components (810b), each having one or more leads (1420), respectively inserted into the one or more apertures (430d) wherein one or more of the one or more leads (1420) is in communication with a respective surface of the one or more apertures (430d).

33. The subassembly of claim 32 further comprising:
one or more vias (1030b) extending through the negative master (420e) and exposing one or more of the one or more leads (1420).
